(19) United States
(12) Patent Application Publication
(10) Pub. No.: US 2025/0118632 A1
(43) Pub. Date: Apr. 10, 2025

(54) MEMORY DEVICES WITH SWITCHABLE POWER DELIVERY PATHS

(71) Applicant: Taiwan Semiconductor Manufacturing Company, Ltd., Hsinchu (TW)

(72) Inventors: Yi-Hsin Nien, Hsinchu City (TW); Chih-Yu Lin, Hsinchu City (TW); Hidehiro Fujiwara, Hsinchu City (TW); Yen-Huei Chen, Hsinchu City (TW)

(73) Assignee: Taiwan Semiconductor Manufacturing Company, Ltd., Hsinchu (TW)

(21) Appl. No.: 18/483,739

(22) Filed: Oct. 10, 2023

(51) Int. Cl. H01L 23/48; H10B 10/00

(52) U.S. Cl. CPC H01L 23/481; H10B 10/12

(57) ABSTRACT

A memory device may comprise a substrate, a plurality of memory cells, and a header device. The substrate may have a first side and a second side opposite to each other. The plurality of memory cells may be formed on the first side of the substrate. The header device may be formed on the first side of the substrate. The header device can be configured to selectively couple a supply voltage through a first combination of power delivery paths or a second combination of power delivery paths to the plurality of memory cells based on a control signal.

### BACKGROUND

Developments in electronic devices, such as computers, portable devices, smart phones, internet of thing (IoT) devices, etc., have prompted increased demands for memory devices. As a memory device (e.g., static random-access memory (SRAM)) is scaled down in size, an oxide diffusion (OD) area becomes smaller, leading to reduced backside power vias with a high resistance. This results in a larger voltage drop (e.g., IR drop), which degrades a speed of the SRAM.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of an example memory device with switchable power delivery paths, in accordance with some embodiments.

FIG. 2 illustrates a frontside layout design and a backside layout design of an example memory device with switchable power delivery paths of FIG. 1, in accordance with some embodiments.

FIG. 3 illustrates an example circuit diagram of an example memory device with switchable power delivery paths of FIG. 1, in accordance with some embodiments.

FIG. 4 illustrates an example circuit diagram of an example memory device with switchable power delivery paths of FIG. 1, in accordance with some embodiments.

FIG. 5 illustrates a frontside layout design and a backside layout design of an example memory device with switchable power delivery paths of FIG. 1, in accordance with some embodiments.

FIG. 6 illustrates an example circuit diagram of an example memory device with switchable power delivery paths of FIG. 1, in accordance with some embodiments.

FIG. 7 illustrates an example circuit diagram of an example memory device with switchable power delivery paths of FIG. 1, in accordance with some embodiments.

FIG. 8 illustrates a flow chart of an example method for operating memory devices with switchable power delivery paths of FIG. 1, in accordance with some embodiments.

FIG. 9 illustrates a flow chart of an example method for fabricating memory devices with switchable power delivery paths of FIG. 1, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In a static random-access memory (SRAM), NMOS and PMOS transistors are formed in oxide definition (OD) areas. The OD area, sometimes labeled as an “oxide diffusion” area, defines an active area for each transistor, i.e., the area where the source, drain and channel under the gate of transistor are formed. The OD is defined to be between inactive areas, such as shallow trench isolation (STI) or field oxide (FOX) areas. An OD area contains PMOS or NMOS transistors. A discontinuity (gap) separates adjacent OD regions.

A power supply (e.g., VDD and VSS) in a memory device (e.g., a SRAM) can be uniformly distributed through metal rails and stripes (e.g., power delivery network (PDN) or power grid). Each metal layer used in the PDN may have finite resistivity. When current flow through the power delivery network, a part of the applied voltage may be dropped in the PDN as per the Ohm's law. The amount of voltage drop can be V=I*R, which is called an IR drop. To mitigate IR drop and improve SRAM performance, a larger oxide diffusion (OD) area with smaller backside power vias resistance is required. The OD area can be the area where the source, drain and channel under the gate of transistor are formed. In small OD areas, the implementation of backside power delivery (BVD) may result in a significant IR drop. When the backside BVD has a high resistance (high-R), this IR drop causes a reduction in the VDDPUx voltage, leading to a degradation in SRAM speed and performance. The IR drop can be mitigated by employing frontside power assistance (e.g., frontside power delivery) from a larger OD, forming a parallel circuit. The frontside power assistance may help to counteract the effects of the backside IR drop, improving overall power delivery and performance in the SRAM.

The present disclosure provides various embodiments of methods to address issues of leakage in a standby/retention mode of a static random-access memory (SRAM) and to achieve a high-speed operation in a mission mode. For example, a footer/header system is introduced. This system allows for the switching between single-side and double-side power rails. By doing so, the SRAM can minimize leakage during standby/retention mode, conserving power when not actively accessed. On the other hand, during mission mode, the double-side power rail may facilitate a high-speed operation, ensuring optimal performance when the SRAM is in use.

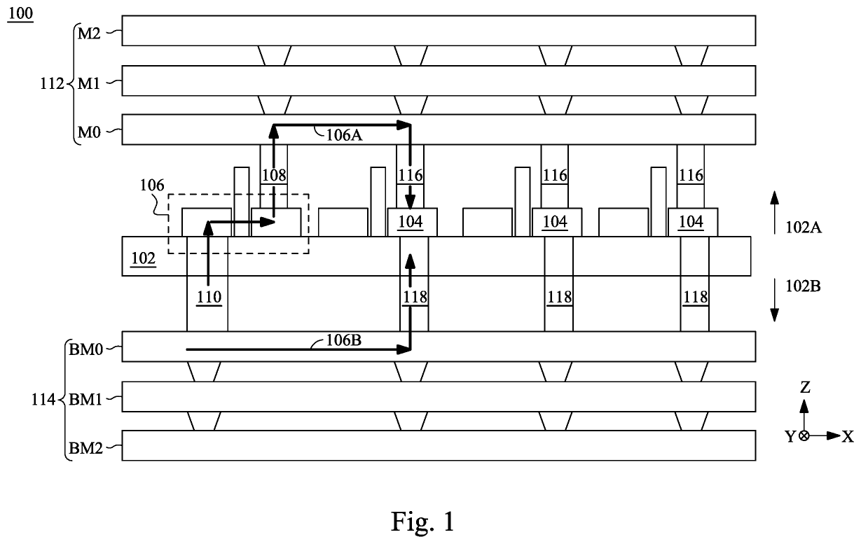

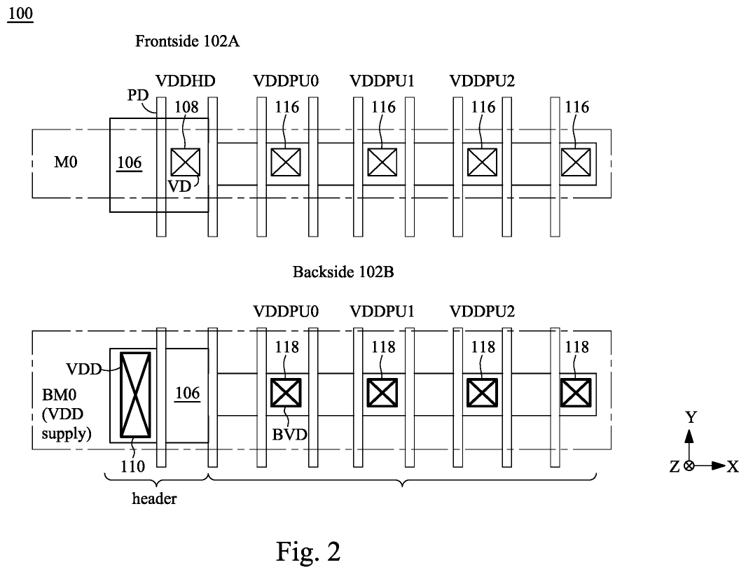

FIG. 1 is a cross-sectional view of an example memory device (e.g., SRAM) 100 with switchable power delivery paths, in accordance with some embodiments. FIG. 2 illustrates a frontside layout design and a backside layout design of an example memory device 100 with switchable power delivery paths of FIG. 1, in accordance with some embodiments. In the illustrated embodiment of FIG. 1, the memory device 100 includes a substrate 102, a plurality of memory cells 104, a header device 106, a first conductor structure 114, a second conductor structure 112, a first via structure (e.g., header BVD) 110, a plurality of second via structures (e.g., BVD) 118, a third via structure (e.g., header VD) 108, and a plurality of fourth via structures (e.g., VD) 116. The cross-sectional view of FIG. 1 is cut along the lengthwise direction of the memory device 100 (e.g., the X direction). Despite not being explicitly shown in FIG. 1, the components of the memory device 100 may be operatively coupled to each other and to a control logic circuit and/or a power source. For example, the header device 106 may be electrically coupled at least to the memory cells 104, in some embodiments. A control logic circuit (not shown in FIG. 1) is a hardware component that can control the coupled components (e.g., 102 through 118). In some embodiments, the memory device 100 may have a larger oxide diffusion (OD) area and a low resistance backside power delivery (BVD).

The substrate 102 may have a first side 102A and a second side 102B opposite to each other. The substrate 102 may be a semiconductor substrate, such as a bulk semiconductor, a semiconductor-on-insulator (SOI) substrate, or the like, which may be doped (e.g., with a p-type or an n-type dopant) or undoped. The substrate may be a wafer, such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

The plurality of memory cells 104 may be formed on the first side 102A of the substrate 102. The plurality of memory cells 104 can be a hardware component that stores data. Each of the plurality of memory cells 104 may have p-type conductivity or n-type conductivity. In one aspect, the plurality of memory cells 104 can be embodied as a semiconductor memory device. The plurality of memory cells 104 may include a number of rows (e.g., R₁, R₂, R₃ . . . R_{M}), each extending in a first direction (e.g., X-direction) and a number of columns (e.g., C₁, C₂, C₃ . . . C_{N}), each extending in a second direction (e.g., Y-direction). Each of the rows/columns may include one or more conductive structures. In some embodiments, each memory cell 104 is arranged in the intersection of a corresponding row and a corresponding column and can be operated according to voltages or currents through the respective conductive structures of the column and row. A row decoder (not shown in FIG. 1) can be a hardware component that can receive a row address of the plurality of memory cells 104 and assert a conductive structure (e.g., a word line) at that row address. A column decoder (not shown in FIG. 1) can be a hardware component that can receive a column address of the plurality of memory cells 104 and assert one or more conductive structures (e.g., a bit line, a source line) at that column address.

The header device 106 may be formed on the first side 102A of the substrate 102. The header device 106 can be configured to selectively couple a supply voltage (e.g., VDD or VSS) through a first combination of power delivery paths (e.g., 106A and 106B) or a second combination of power delivery paths (e.g., only 106B) to the plurality of memory cells 104 based on a control signal (e.g., a PD signal). In some embodiments, the header device 106 may have p-type conductivity (e.g., p-type transistor) and the supply voltage can be VDD. In certain embodiments, the header device 106 may have n-type conductivity (e.g., n-type transistor) and the supply voltage can be VSS. The header device 106 can be configured as a footer. The header device 106 can also be configured as a header. A footer can be a circuit that allows for the disconnection or reduction of power supply to specific circuit blocks or sections. A header can be a circuit that enables the connection or enhancement of power supply to specific circuit blocks or sections. For embodiments using a header, a power line (e.g., a first combination of power delivery paths (e.g., 106A and 106B) and/or a second combination of power delivery paths (e.g., only 106B)) having a power voltage (e.g., VDD) can be coupled with the memory cells 104. In some embodiments, the supply voltage can be VDD or VSS.

In some embodiments, the header device 106 may be electrically coupled to the first conductor structure 114 through the first via structure (e.g., header BVD) 110. The first conductor structure 114 can be disposed on the second side 102B of the substrate 102. The first conductor structure 114 can be configured to provide the supply voltage (e.g., VDD or VSS). The first via structure 110 can be disposed on the second side 102B of the substrate 102. The first via structure 110 can be configured to electrically couple the first conductor structure 114 to a first source/drain terminal of the header device 106. The plurality of second via structures 118 can be disposed on the second side 102B of the substrate 102. The plurality of second via structures (e.g., BVD) 118 can be configured to electrically couple the first conductor structure 114 to the memory cells 104, respectively.

On the backside 102B, the memory device 100 may include the first conductor structure 114. The first conductor structure 114 may include a number of backside metallization layers (e.g., BM0, BM1, BM2). Each of the backside metallization layers may include a number of back-end interconnect structures, metal lines and via structures, embedded in a corresponding dielectric material (e.g., an inter-metal dielectric (IMD)). For example, the memory device 100 includes the first conductor structure 114, BM0, BM1, and BM2. Although three backside metallization layers are shown, it should be understood that the memory device 100 can include any number of backside metallization layers while remaining within the scope of the present disclosure. The backside metallization layer BM0 may include metal line (which is sometimes referred to as “BM0 track”), and via structures (which are sometimes referred to as “BV0s”); the backside metallization layer BM1 may include metal line (which is sometimes referred to as “BM1 track”), and via structures (which are sometimes referred to as “BV1s”); and the backside metallization layer BM2 may include metal line (which is sometimes referred to as “BM2 track”). The second via structures 118 can allow the memory cells 104 to be in electrical contact with the BM2 track through the BM0 track, BV0, BM1 track, and BV1.

In some embodiments, the header device 106 may be electrically coupled to the second conductor structure 112 through the third via structure (e.g., header VD) 108. The second conductor structure 112 can be disposed on the first side 102A of the substrate 102. The second conductor structure 112 can be configured to deliver the supply voltage (e.g., VDD or VSS) to the memory cells 104. The third via structure 108 can be disposed on the first side 102A of the substrate 102. The third via structure 108 can be configured to electrically couple a second source/drain terminal of the header device 106 to the second conductor structure 112. The plurality of fourth via structures 116 can be disposed on the first side 102A of the substrate 102. The plurality of fourth via structures (e.g., VD) 116 can be configured to electrically couple the second conductor structure 112 to the memory cells 104, respectively.

In some embodiments, the first via structure (e.g., header BVD) 110 has a first width extending along a first direction (e.g., Y-direction) perpendicular to a second direction (e.g., X-direction) along which the first conductor structure extends. The second via structures (e.g., BVD) 118, the third via structures (e.g., header VD) 108, and the fourth via structures (e.g., VD) 116 may have a second width extending along the first direction (e.g., Y-direction). The first width (e.g., 30 nm) is substantially greater than the second width (e.g., 20 nm). In other words, the first via structure (e.g., header BVD) 110 is larger than the third via structures (e.g., header VD) 108.

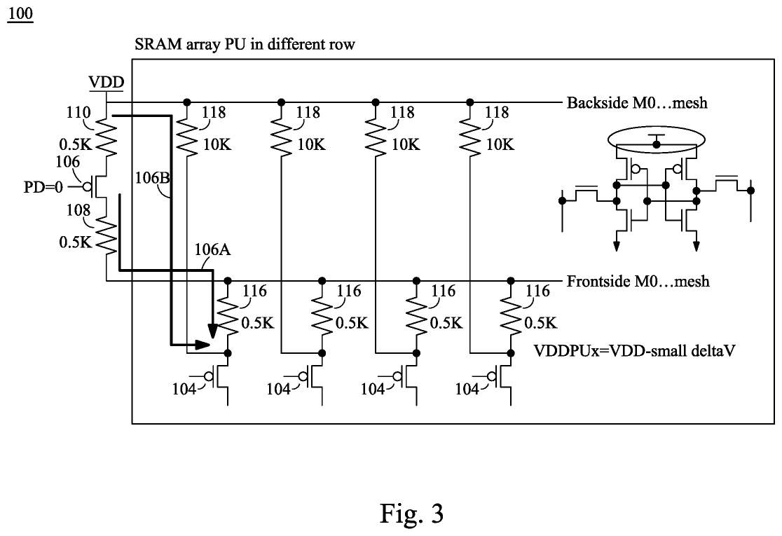

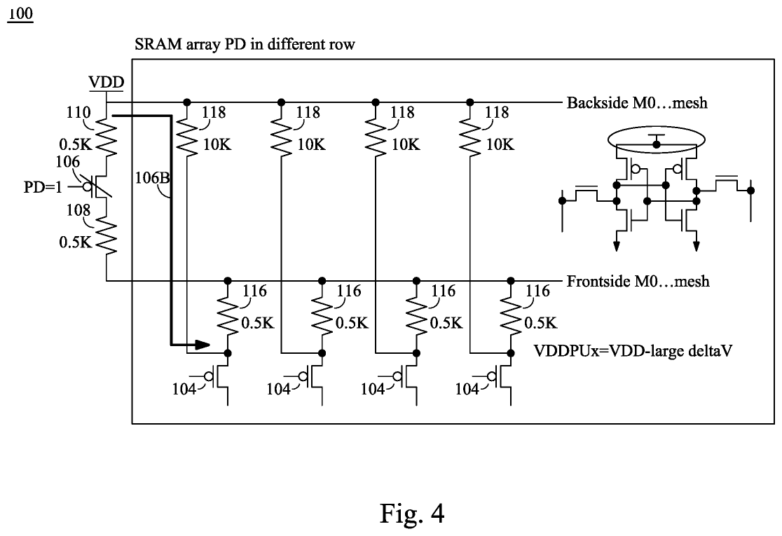

Over the third (e.g., header VD) and fourth via structures (e.g., VD) 108, 116, the memory device 100 may include the second conductor structure 112. The second conductor structure 112 may include a number of frontside metallization layers (e.g., M0, M1, M2). Each of the frontside metallization layers may include a number of back-end interconnect structures, metal lines and via structures, embedded in a corresponding dielectric material (e.g., an inter-metal dielectric (IMD)). For example, the memory device 100 includes the second conductor structure 112, M0, M1, and M2. Although three frontside metallization layers are shown, it should be understood that the memory device 100 can include any number of frontside metallization layers while remaining within the scope of the present disclosure. The frontside metallization layer M0 may include metal lines (which are sometimes referred to as “M0 tracks”), and via structures (which are sometimes referred to as “V0”); the frontside metallization layer M1 includes metal lines (which are sometimes referred to as “M1 tracks”), and via structures (which are sometimes referred to as “V1”); and the frontside metallization layer M2 includes metal lines (which are sometimes referred to as “M2 tracks”). The fourth via structures 116 can allow the memory cells 104 to be in electrical contact with the M2 track through the M0 track, V0, M1 track, and V1. The operations of the memory device 100 will be described with the following FIGS. 3 and 4.

FIG. 3 illustrates an example circuit diagram of an example memory device with switchable power delivery paths of FIG. 1, in accordance with some embodiments. FIG. 4 illustrates an example circuit diagram of an example memory device with switchable power delivery paths of FIG. 1, in accordance with some embodiments. The header device may have p-type conductivity and the supply voltage can be VDD. There can be power delivery paths from the first conductor structure 114 to one of the memory cells 104. A first path 106B may extend from the first conductor structure 114, through one of the second via structures 118, and to one of the memory cells 104. A second path 106A may extend from the first conductor structure 114, through the first via structure 110, the header device 106, the third via structure 108, and one of the fourth via structures 116, and to one of the memory cells 104. A first combination of power delivery paths may comprise the first path 106B and the second path 106A. A second combination of power delivery paths may comprise the first path 106B.

In a mission mode (e.g., when PD=0), the header device 106 can be turned on. The first combination of power delivery paths (e.g., first path 106B+second path 106A) can be selected. In such case, due to the low resistance (low-R) of the header BVD 110, a strong power supply voltage for pull-up transistors (e.g., VDDPUx) can be strong (lesser IR drop). This low resistance leads to lesser IR drop, making the pull-up transistors function more efficiently and effectively, leading to improved speed and performance in a SRAM. In such case, VDDPUx=VDD−small deltaV. For example, the VDD can be 1 V. After the IR drop (e.g., deltaV=0.02 V), the VDDPUx may become 0.98 V.

In a standby or retention mode (e.g., when PD=1), the header device 106 can be turned off. The second combination of power delivery paths (e.g., first path 106B) can be selected. In such case, the power is only delivered by the backside power delivery (BVD). Due to the high resistance (high-R) for the plurality of second via structures (e.g., BVD) 118, a power supply voltage for pull-up transistors (e.g., VDDPUx) may have a large IR drop. However, this configuration can lead to lower power consumption in the SRAM latch. In such case, VDDPUx=VDD−large deltaV. For example, the VDD can be 1 V. After the IR drop (e.g., deltaV=0.1 V), the VDDPUx may become 0.9 V.

When the control signal (e.g., PD signal) is provided at a first logic state (e.g., when PD=0), the header device 106 can be configured to couple the supply voltage (e.g., VDD) through the first combination of power delivery paths (e.g., first path 106B+second path 106A) to one or more of the memory cells 104. When the control signal (e.g., PD signal) is provided at a second logic state (e.g., when PD=1), the header device 106 can be configured to couple the supply voltage (e.g., VDD) through the second combination of power delivery paths (e.g., first path 106B) to one or more of the memory cells 104.

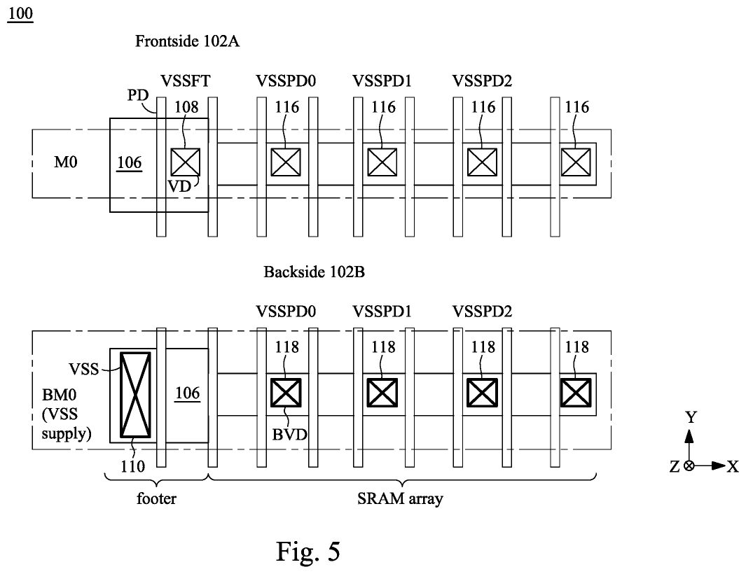

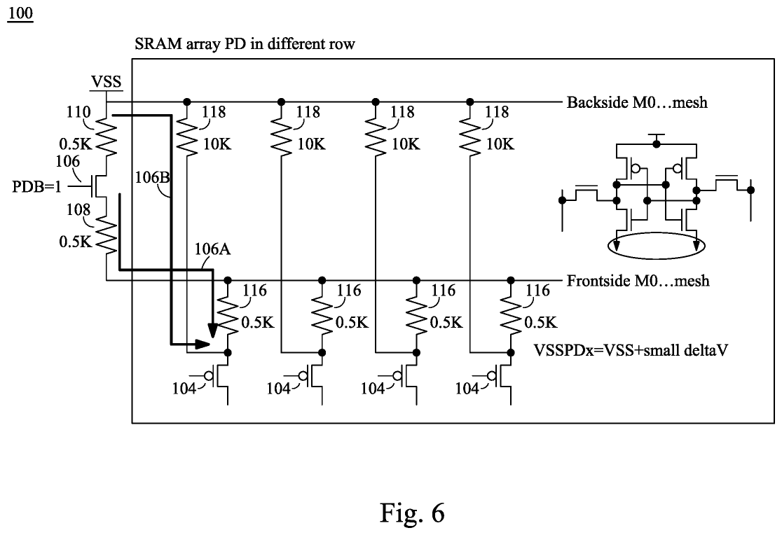

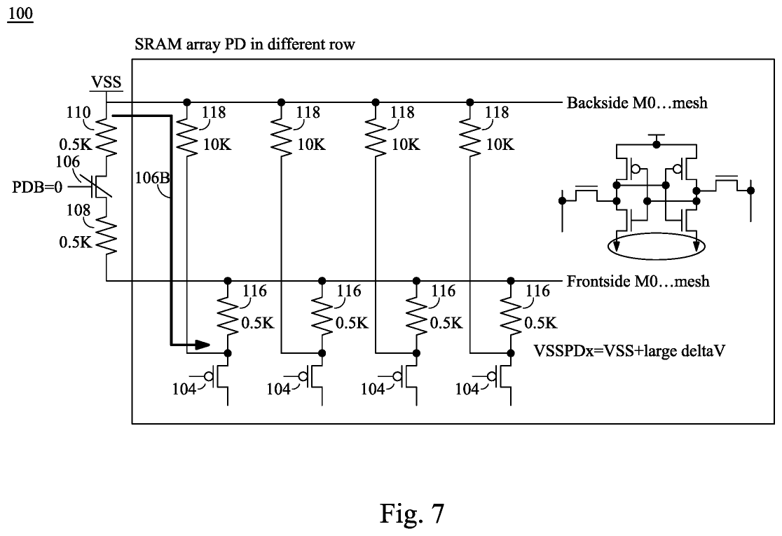

FIG. 5 illustrates a frontside layout design and a backside layout design of an example memory device with switchable power delivery paths of FIG. 1, in accordance with some embodiments. FIG. 6 illustrates an example circuit diagram of an example memory device with switchable power delivery paths of FIG. 1, in accordance with some embodiments. FIG. 7 illustrates an example circuit diagram of an example memory device with switchable power delivery paths of FIG. 1, in accordance with some embodiments.

The system 100 of FIGS. 5, 6, 7 is substantially similar to the system 100 of FIG. 1, except for the header device 106 with a different type conductivity (e.g., n-type) and different supply voltage (e.g., VSS). The header device 106 can be configured for a footer. For embodiments using a footer, a power line (e.g., a first combination of power delivery paths (e.g., 106A and 106B) and/or a second combination of power delivery paths (e.g., only 106B)) having a power voltage (e.g., VSS) can be coupled with the memory cells 104.

In a mission mode (e.g., when PD=1), the header device 106 can be turned on. The first combination of power delivery paths (e.g., first path 106B+second path 106A) can be selected. In such case, due to the low resistance (low-R) of the header BVD 110, a strong power supply voltage for pull-down transistors (e.g., VSSPDx) can be strong (lesser IR drop). This low resistance leads to lesser IR drop, making the pull-down transistors function more efficiently and effectively, leading to improved speed and performance in a SRAM. In such case, VSSPDx=VSS+small deltaV. For example, the VSS can be 0 V. After the IR drop (e.g., deltaV=0.02 V), the VSSPDx may become 0.02 V.

In a standby or retention mode (e.g., when PD=0), the header device 106 can be turned off. The second combination of power delivery paths (e.g., first path 106B) can be selected. In such case, the power is only delivered by the backside power delivery (BVD). Due to the high resistance (high-R) for the plurality of second via structures (e.g., BVD) 118, a power supply voltage for pull-down transistors (e.g., VSSPDx) may have a large IR drop. However, this configuration can lead to lower power consumption in the SRAM latch. In such case, VSSPDx=VDD+large deltaV. For example, the VDD can be 0 V. After the IR drop (e.g., deltaV=0.1 V), the VSSPDx may become 0.1 V.

When the control signal (e.g., PD signal) is provided at a first logic state (e.g., when PD=1), the header device 106 can be configured to couple the supply voltage (e.g., VSS) through the first combination of power delivery paths (e.g., first path 106B+second path 106A) to one or more of the memory cells 104. When the control signal (e.g., PD signal) is provided at a second logic state (e.g., when PD=0), the header device 106 can be configured to couple the supply voltage (e.g., VSS) through the second combination of power delivery paths (e.g., first path 106B) to one or more of the memory cells 104.

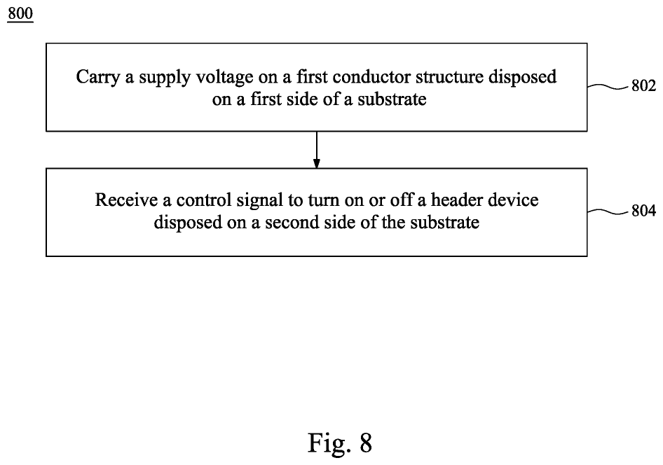

FIG. 8 illustrates a flow chart of an example method for operating memory devices with switchable power delivery paths of FIG. 1, in accordance with some embodiments. The method 800 may be used to operate the memory 100. It is noted that the method 800 is merely an example and is not intended to limit the present disclosure. Accordingly, it is understood that additional operations may be provided before, during, and after the method 800 of FIG. 8, and that some other operations may only be briefly described herein.

The method 800 starts with operation 802 in which memory devices 100 carrying a supply voltage (e.g., VDD or VSS) on a first conductor structure 114 disposed on a first side 102B of a substrate 102. For example in FIG. 1, the header device 106 can be configured to selectively couple a supply voltage (e.g., VDD or VSS) through a first combination of power delivery paths (e.g., 106A and 106B) or a second combination of power delivery paths (e.g., only 106B) to the memory cells 104 based on a control signal (e.g., a PD signal). In some embodiments, the first combination of power delivery paths may include: a first path 106 B and a second path 106A. The first path 106B may extend from the first conductor structure 114, through one of a plurality of first via structures disposed on the first side 102B, and to the memory cell 104. The second path 106A may extend from the first conductor structure 114, through the header device 106 and one of a plurality of second via structures 108, 112, 116 disposed on the second side 102A, and to the memory cell 104. The second combination of power delivery paths may include a single path 106B. The single path 106B may extend from the first conductor structure 114, through one of the plurality of first via structures 118 disposed on the first side 102B, and to the memory cell 104.

The method 800 continues to operation 804 in which receiving a control signal to turn on or off a header device 106 disposed on a second side 102A of the substrate 102. For example, the header device 106 may have p-type conductivity and the supply voltage can be VDD. In FIG. 3, when the header device 106 is turned on (e.g., PD=0), causing the supply voltage (e.g., VDD) through a first combination of power delivery paths (e.g., first path 106B+second path 106A) to be delivered to a memory cell 104 disposed on the second side 102A. In FIG. 4, when the header device 106 is turned off (e.g., PD=1), causing the supply voltage (e.g., VDD) through a second combination of power delivery paths (e.g., first path 106B) to be delivered to the memory cell 104. For another example, the header device may have n-type conductivity and the supply voltage can be VSS. In FIG. 6, when the header device 106 is turned on (e.g., PD=1), causing the supply voltage (e.g., VSS) through a first combination of power delivery paths (e.g., first path 106B+second path 106A) to be delivered to a memory cell 104 disposed on the second side 102A. In FIG. 7, when the header device 106 is turned off (e.g., PD=0), causing the supply voltage (e.g., VSS) through a second combination of power delivery paths (e.g., first path 106B) to be delivered to the memory cell 104.

The memory design incorporates several features to optimize power consumption and performance. One such feature is the addition of a header or footer with a larger oxide diffusion (OD) area and vias to efficiently supply power (VDD/VSS) to the SRAM. During a mission mode, when the header or footer is activated, the power supply becomes dual-sided, utilizing both frontside and backside power delivery to ensure a healthier power environment within the SRAM. This improves the overall performance and speed of the memory device.

Conversely, in a standby or retention mode, when the header or footer is turned off, the power supply switches to single-sided (backside) delivery. This configuration results in a weaker power supply within the SRAM, specifically tailored to facilitate data retention while minimizing power consumption. This energy-saving approach allows the memory device to retain data efficiently without unnecessary power drain. The present disclosure provides a power management approach applicable to multi-port SRAM with latch-based memory.

In one aspect of the present disclosure, a memory device is disclosed. The memory device includes a substrate having a first side and a second side opposite to each other; a plurality of memory cells formed on the first side of the substrate; a header device formed on the first side of the substrate. The header device is configured to selectively couple a supply voltage through a first combination of power delivery paths or a second combination of power delivery paths to the plurality of memory cells based on a control signal.

In another aspect of the present disclosure, a memory device is disclosed. The memory device includes a plurality of memory cells formed on a frontside of a substrate; a header device also formed on the front side; a first conductor structure disposed on the a backside of the substrate and configured to provide a supply voltage; a first via structure disposed on the backside and configured to electrically couple the first conductor structure to a first source/drain terminal of the header device; a plurality of second via structures disposed on the backside and configured to electrically couple the first conductor structure to the memory cells, respectively; a second conductor structure disposed on the frontside and configured to deliver the supply voltage to the memory cells; a third via structure disposed on the frontside and configured to electrically couple a second source/drain terminal of the header device to the second conductor structure; and a plurality of fourth via structures disposed on the frontside and configured to electrically couple the second conductor structure to the memory cells, respectively.

In one aspect of the present disclosure, a method for operating memory devices is disclosed. The method includes carrying a supply voltage on a first conductor structure disposed on a first side of a substrate. The method includes receiving a control signal to turn on or off a header device disposed on a second side of the substrate. The method includes, when the header device is turned on, causing the supply voltage through a first combination of power delivery paths to be delivered to a memory cell disposed on the second side. The method includes, when the header device is turned off, causing the supply voltage through a second combination of power delivery paths to be delivered to the memory cell.

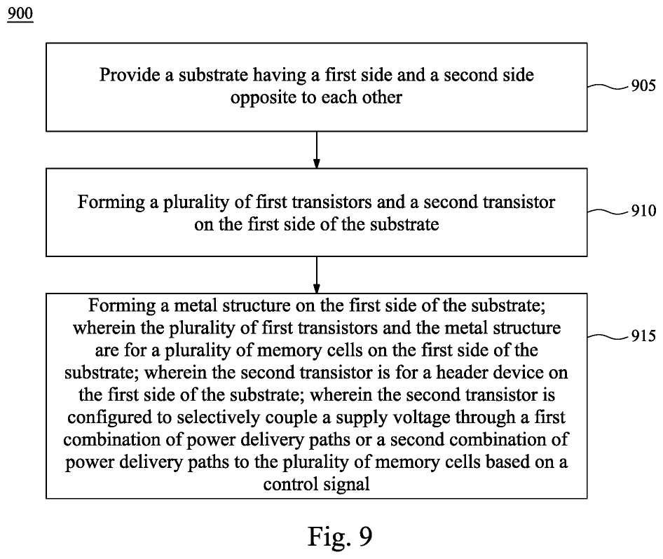

FIG. 9 illustrates a flow chart of an example method for fabricating memory devices with switchable power delivery paths of FIG. 1, in accordance with some embodiments. It is understood that FIG. 9 and FIG. 1 have been simplified for a better understanding of the concepts of the present disclosure. Accordingly, it should be noted that additional processes may be provided before, during, and after the method of FIG. 9, and that some other processes may only be briefly described herein.

Referring now to FIG. 9, operation 905 can provide a substrate 102. The substrate 102 may have a first side 102A and a second side 102B opposite to each other. The substrate 102 may be a semiconductor substrate, such as a bulk semiconductor, a semiconductor-on-insulator (SOI) substrate, or the like, which may be doped (e.g., with a p-type or an n-type dopant) or undoped.

Next, the method 900 proceeds to operation 910 of forming a plurality of first transistors and a second transistor on the first side 102A of the substrate 102. The plurality of first transistors can be a hardware component that stores data. Each of the plurality of first transistors may have p-type conductivity or n-type conductivity. In one aspect, the plurality of first transistors can be embodied as a semiconductor memory device. In some embodiments, the second transistor can be for a header device 106 on the first side 102A of the substrate 102. The second transistor may have have p-type conductivity or n-type conductivity.

Next, the method 900 proceeds to operation 915 of forming a metal structure (e.g., word lines and/or bit lines, interconnect) on the first side 102A of the substrate 102. The plurality of first transistors and the metal structure (e.g., word lines and/or bit lines) can be for a plurality of memory cells on the first side 102A of the substrate 102. In some embodiments, a second conductor structure 112 can be formed on the first side 102A of the substrate 102. The second conductor structure 112 can be configured to deliver the supply voltage to the first transistors. A third via structure 108 can be formed on the first side 102A of the substrate 102. The third via structure 108 can be configured to electrically couple a second source/drain terminal of the second transistor to the second conductor structure 112. A plurality of fourth via structures 108 can be formed on the first side 102A of the substrate 102. The plurality of fourth via structures 108 can be configured to electrically couple the second conductor structure 112 to the first transistors, respectively. A first conductor structure 114 can be formed on the second side 102B of the substrate 102. The first conductor structure 114 can be configured to provide the supply voltage. A first via structure 110 can be formed on the second side 102B of the substrate 102. The first via structure 110 can be configured to electrically couple the first conductor structure 114 to a first source/drain terminal of the second transistor. A plurality of second via structures 118 can be formed on the second side 102B of the substrate 102. The plurality of second via structures 118 can be configured to electrically couple the first conductor structure 114 to the first transistors, respectively.

In some embodiments, the second transistor can be configured to selectively couple a supply voltage through a first combination of power delivery paths (e.g., 106A and 106B) or a second combination of power delivery paths (e.g., only 106B) to the plurality of memory cells 104 (e.g., first transistors) based on a control signal. The first combination of power delivery paths (e.g., 106A and 106B) may include: a first path 106B extending from the first conductor structure 114, through one of a plurality of first via structures disposed on the second side, and to the first transistors, and a second path 106A extending from the first conductor structure 114, through the second transistor and one of a plurality of second via structures disposed on the first side, and to the first transistor. The second combination of power delivery paths 106A may include: a single path extending from the first conductor structure 114, through one of the plurality of first via structures 118 disposed on the second side, and to the first transistor.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a substrate having a first side and a second side opposite to each other;
a plurality of memory cells formed on the first side of the substrate;
a header device formed on the first side of the substrate;
wherein the header device is configured to selectively couple a supply voltage through a first combination of power delivery paths or a second combination of power delivery paths to the plurality of memory cells based on a control signal.

2. The memory device of claim 1, further comprising:
a first conductor structure disposed on the second side of the substrate and configured to provide the supply voltage;
a first via structure disposed on the second side of the substrate and configured to electrically couple the first conductor structure to a first source/drain terminal of the header device;
a plurality of second via structures disposed on the second side of the substrate and configured to electrically couple the first conductor structure to the memory cells, respectively;
a second conductor structure disposed on the first side of the substrate and configured to deliver the supply voltage to the memory cells;
a third via structure disposed on the first side of the substrate and configured to electrically couple a second source/drain terminal of the header device to the second conductor structure; and
a plurality of fourth via structures disposed on the first side of the substrate and configured to electrically couple the second conductor structure to the memory cells, respectively.

3. The memory device of claim 2, wherein the first combination of power delivery paths include:
a first path extending from the first conductor structure, through one of the second via structures, and to one of the memory cells; and
a second path extending from the first conductor structure, through the first via structure, the header device, the third via structure, and one of the fourth via structures, and to one of the memory cells.

4. The memory device of claim 3, wherein the header device is turned on.

5. The memory device of claim 2, wherein the second combination of power delivery paths include:
a path extending from the first conductor structure, through one of the second via structures, and to one of the memory cells.

6. The memory device of claim 5, wherein the header device is turned off.

7. The memory device of claim 1, wherein the supply voltage is VDD or VSS.

8. The memory device of claim 2, wherein the first via structure has a first width extending along a first direction perpendicular to a second direction along which the first conductor structure extends, and the second via structures, the third via structures, and the fourth via structures have a second width extending along the first direction.

9. The memory device of claim 8, wherein the first width is substantially greater than the second width.

10. The memory device of claim 1, wherein when the control signal is provided at a first logic state, the header device is configured to couple the supply voltage through the first combination of power delivery paths to one or more of the memory cells, and when the control signal is provided at a second logic state, the header device is configured to couple the supply voltage through the second combination of power delivery paths to one or more of the memory cells.

11. A memory device, comprising:
a plurality of memory cells formed on a frontside of a substrate;
a header device also formed on the front side;
a first conductor structure disposed on the a backside of the substrate and configured to provide a supply voltage;
a first via structure disposed on the backside and configured to electrically couple the first conductor structure to a first source/drain terminal of the header device;
a plurality of second via structures disposed on the backside and configured to electrically couple the first conductor structure to the memory cells, respectively;
a second conductor structure disposed on the frontside and configured to deliver the supply voltage to the memory cells;
a third via structure disposed on the frontside and configured to electrically couple a second source/drain terminal of the header device to the second conductor structure; and
a plurality of fourth via structures disposed on the frontside and configured to electrically couple the second conductor structure to the memory cells, respectively.

12. The memory device of claim 11, wherein when the header device is turned on, the supply voltage is delivered to one or more of the memory cells through a first path and a second path.

13. The memory device of claim 12, wherein the first path extends from the first conductor structure, through respective ones of the second via structures, and to the one or more memory cells, and the second path extends from the first conductor structure, through the first via structure, the header device, the third via structure, the second conductor structure, and respective ones of the fourth via structures, and to the one or more memory cells.

14. The memory device of claim 11, wherein when the header device is turned off, the supply voltage is delivered to one or more of the memory cells through a single path.

15. The memory device of claim 14, wherein the single path extends from the first conductor structure, through respective ones of the second via structures, and to the one or more memory cells.

16. The memory device of claim 11, wherein the header device has p-type conductivity and the supply voltage is VDD.

17. The memory device of claim 11, wherein the header device has n-type conductivity and the supply voltage is VSS.

18. The memory device of claim 11, wherein the first conductor structure and the second conductor structure each extend along a first direction, the first via structure has a first width extending along a second direction perpendicular to the first direction, each of the second via structures, the third via structure, and the fourth via structures have a second width extending along the second direction, and the first width is substantially greater than the second width.

19. A method for fabricating memory devices, comprising:
providing a substrate having a first side and a second side opposite to each other;
forming a plurality of first transistors and a second transistor on the first side of the substrate;
forming a metal structure on the first side of the substrate, wherein the plurality of first transistors and the metal structure are for a plurality of memory cells on the first side of the substrate;
wherein the second transistor is for a header device on the first side of the substrate;
wherein the second transistor is configured to selectively couple a supply voltage through a first combination of power delivery paths or a second combination of power delivery paths to the plurality of memory cells based on a control signal.

20. The method of claim 19, further comprising:
forming a second conductor structure on the first side of the substrate, wherein the second conductor structure is configured to deliver the supply voltage to the first transistors;
forming a third via structure on the first side of the substrate, wherein the third via structure is configured to electrically couple a second source/drain terminal of the second transistor to the second conductor structure; and
forming a plurality of fourth via structures on the first side of the substrate, wherein the plurality of fourth via structures are configured to electrically couple the second conductor structure to the first transistors, respectively;
forming a first conductor structure on the second side of the substrate, wherein the first conductor structure is configured to provide the supply voltage;
forming a first via structure on the second side of the substrate, wherein the first via structure is configured to electrically couple the first conductor structure to a first source/drain terminal of the second transistor;
forming a plurality of second via structures on the second side of the substrate, wherein the plurality of second via structures are configured to electrically couple the first conductor structure to the first transistors, respectively.
